(19) United States
(12) Patent Application Publication
(10) Pub. No.: US 2025/0221312 A1
(43) Pub. Date: Jul. 3, 2025

(54) High Temperature Seebeck Energy Generation Device

(71) Applicants: Louis Orndorff, Waldport, OR (US); Timothy Perez, Terrell, TX (US); Hamza Begdouri, Alexandria, VA (US)

(72) Inventors: Louis Orndorff, Waldport, OR (US); Timothy Perez, Terrell, TX (US); Hamza Begdouri, Alexandria, VA (US)

(21) Appl. No.: 18/402,238

(22) Filed: Jan. 2, 2024

(51) Int. Cl. H10N 19/00

(52) U.S. Cl. CPC H10N 19/00

(57) ABSTRACT

An energy generation device using the Seebeck effect comprising a housing, a plurality of thermopiles, an electrical connector, and a power management circuit. The housing is a non-conductive, heat-tolerant material such as a carbon composite or similar. The plurality of thermocouples are positioned within the housing, with portions of the thermocouple being embedded under the outer surface of the housing. When the housing is used in an environment that produces high temperature gradients, such as a reentry spacecraft, the temperature differential between the portions of the thermocouples at the front and rear and interior and exterior of the housing produce a current using the Seebeck effect. The plurality of thermocouples transmit the current using the electrical connector which then transmits the energy to the power management circuit for transformation or storage.

### FIELD OF THE INVENTION

The present invention relates generally to energy generation. Specifically, the present invention is an energy generation device that generates energy using the Seebeck effect.

### BACKGROUND OF THE INVENTION

The Seebeck effect takes advantage of the thermoelectric effect wherein temperature differentials across an electrically conducting material produce a voltage. The use of thermocouples, thermopiles, and heat differentials to produce voltage is well-known in the art. However, applications that take advantage of the Seebeck effect and the Thompson effect to provide additional energy generation for many devices and mechanisms are lacking.

The present invention aims to solve this problem by providing a housing containing an embedded plurality of thermopiles. The housing is adapted for use in high-heat environments, and may comprise a highly heat-tolerant material, such as a carbon composite. The plurality of thermopiles may be positioned in the housing, such that portions of each thermopile are embedded under the outer surface of the housing, while the rest of each thermopile is embedded and contained within the interior of the housing. The housing may have a front end configured to be at a higher heat, and a rear end configured to be at a lower heat. For example, on a spacecraft reentry nose cone, the front of the nose cone will be at a higher heat than the rear of the nose cone. Preferably, a plurality of lines of thermopiles will be used.

The thermopile will be embedded in the housing with the T1 or hot end of the thermopile close to the outer surface of the housing and the T2 or cold end of the thermopile close to the inner surface of the housing. The lines of thermopiles are tightly arranged to form a continuous solid state circuit below the outer surface of the housing. Laid out in tandem, the thermopiles will each be made of a continuous strand of thermocouples, with each strand made of a series of N and P nodes. They are to be made in such a way that the two types of materials will be forged to join together at both ends. For the majority of the present invention, there are to be just five types of materials: the two materials of one thermopile, two types of the other thermopile, and the inert (non-conductive) separation material giving them their basic structure, the separation material ideally being the housing material.

Once the thermopiles have been assembled to their proper design, an electrical wiring system or electrical connector will be installed. This system will have an “in-series” distribution that will take the electrical current produced and transfer it to a power management circuit, ultimately to the storage device placed elsewhere.

The energy generation device will ideally operate when placed under the outer surface of a large vehicle or machine. The movement through an environment at high speeds will create the friction to the surface that will generate extreme temperatures from which thermal energy could be harnessed. The interaction with the high temperature will create an electrical reaction between the differing materials of the thermocouples. The excess electricity will be stored for future use. As the hot end heats up rapidly, a large temperature delta will be created between the two sides. The electricity produced will be transferred from the thermopile to the power management circuit then an electrical storage device that is separate from the device.

### BRIEF DESCRIPTION OF THE DRAWINGS

FIG. 1 shows a perspective view of an embodiment of the present invention having a cone-shaped housing having concentric rings of thermopiles embedded in the housing.

FIG. 2 shows a front view of an embodiment of the present invention having a cone-shaped housing having concentric rings of thermopiles.

FIG. 3 shows a top-down view of an embodiment of the present invention having a cone-shaped housing having concentric rings of thermopiles.

FIG. 4 shows a perspective view of an embodiment of the present invention having a wing-shaped housing having concentric rings of thermopiles.

FIG. 5 shows a top-down view of an embodiment of the present invention having a wing-shaped housing having concentric rings of thermopiles.

FIG. 6 shows a right-side view of an embodiment of the present invention having a wing-shaped housing having concentric rings of thermopiles.

FIG. 7 shows a perspective view of an embodiment of the present invention having a conical-shaped housing having helical spirals of thermopiles.

FIG. 8 shows a front view of an embodiment of the present invention having a conical-shaped housing having helical spirals of thermopiles.

FIG. 9 shows a top-down view of an embodiment of the present invention having a conical-shaped housing having helical spirals of thermopiles.

FIG. 10 shows a perspective view of an embodiment of the present invention having a cone-shaped housing having a helical spiral of thermopiles.

FIG. 11 shows a front view of an embodiment of the present invention having a cone-shaped housing having a helical spiral of thermopiles.

FIG. 12 shows a top-down view of an embodiment of the present invention having a cone-shaped housing having a helical spiral of thermopiles.

FIG. 13 shows a systems view of the present invention configuration and interactions.

### DETAIL DESCRIPTIONS OF THE INVENTION

All illustrations of the drawings are for the purpose of describing selected versions of the present invention and are not intended to limit the scope of the present invention.

It should be understood that the articles “a”, “an”, and “the” encompass both the singular and plural of the referenced component, unless otherwise explicitly stated. For example, reference to “a” thermocouple should encompass “one thermocouple”, “one or more thermocouples”, and “a plurality of thermocouples 300”. Likewise, in the event a component is referred to only in the plural, it should be understood that use of a singular of the component is within the spirit and scope of the present invention, unless otherwise explicitly stated.

The present invention is an energy generation device comprising a housing 100, a plurality of thermopiles 200, an electrical connector 400, and a power management circuit 500.

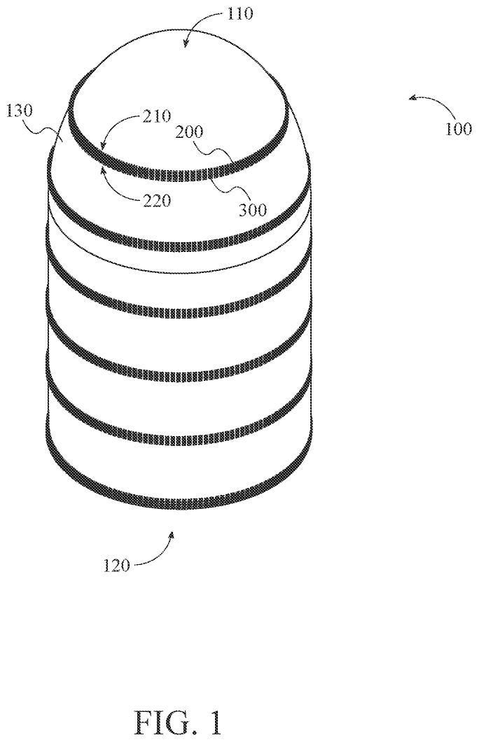

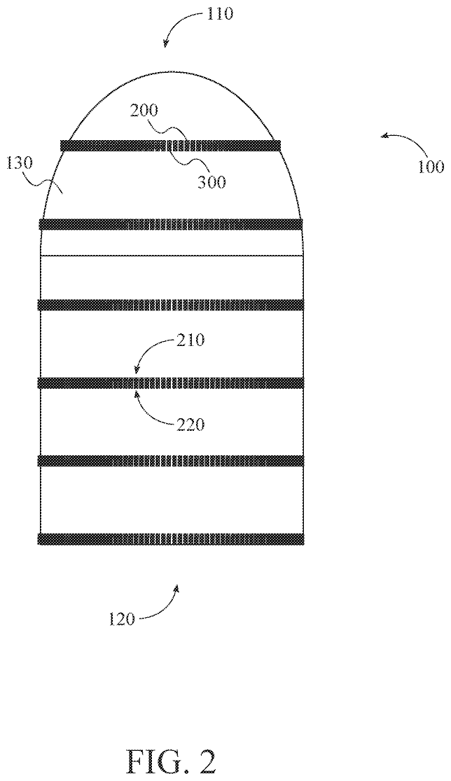

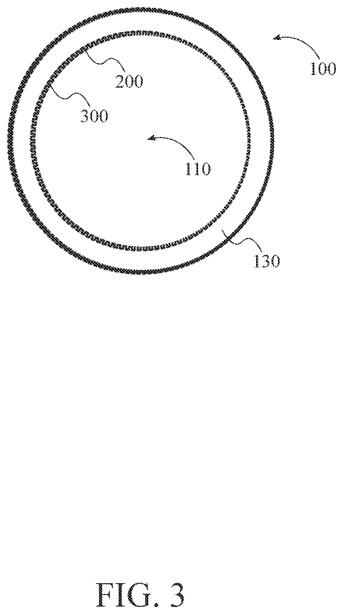

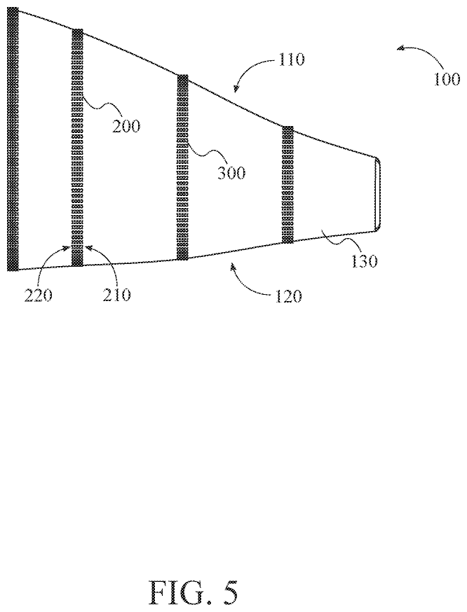

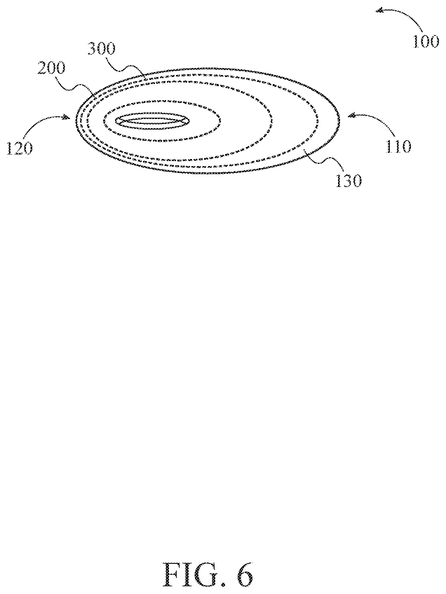

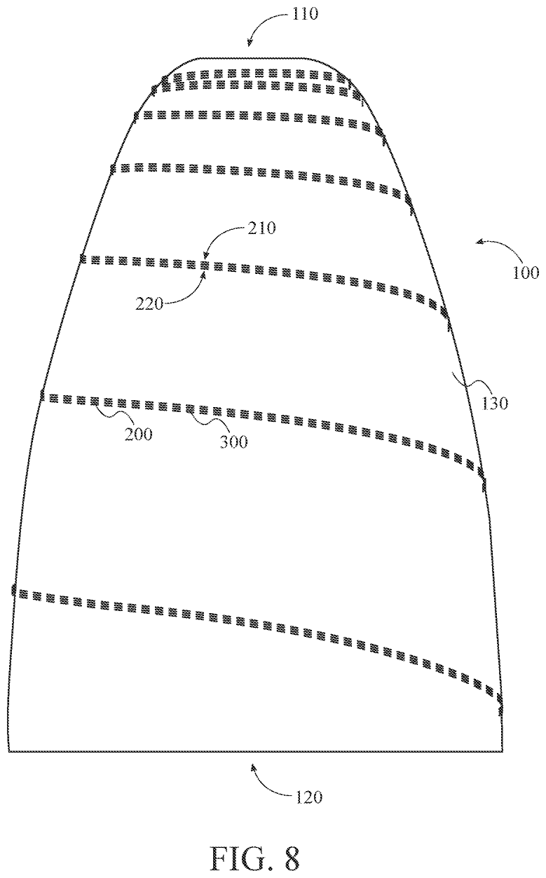

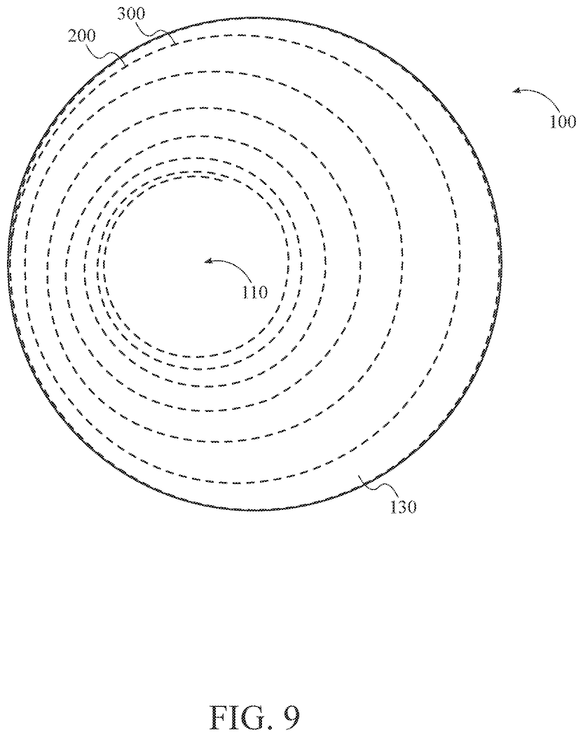

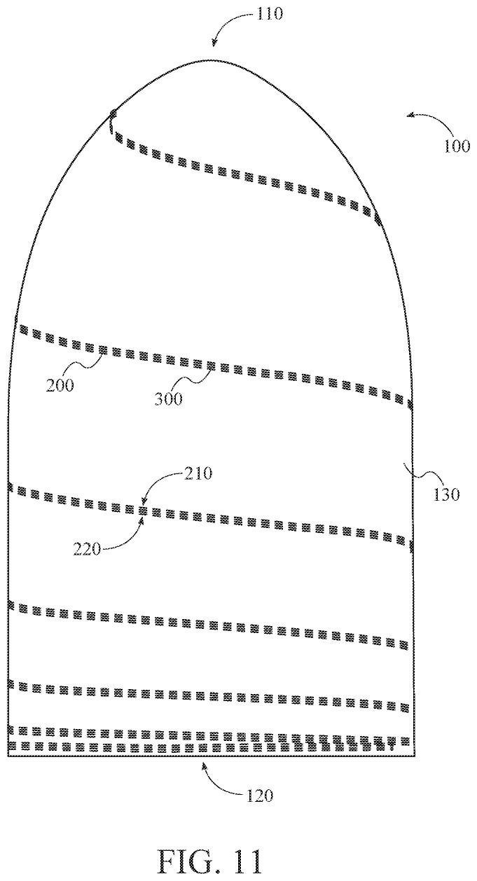

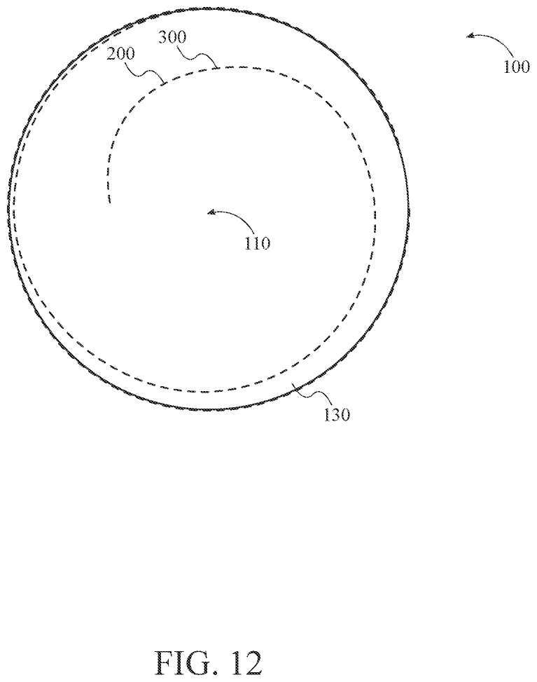

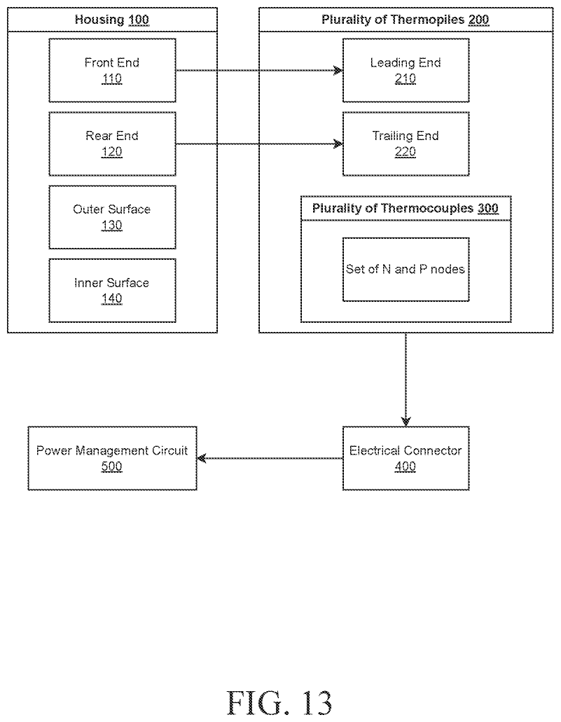

Referring now to the figures, as shown in FIGS. 1-13, the housing 100 is adapted to contain the plurality of thermopiles 200. In the ideal embodiment, the housing 100 may comprise a highly heat-tolerant material, such as solid carbon, carbon composite, a lightweight ceramic material, or any other highly heat-tolerant material that is well-known in the art. The heat-tolerant material should be capable of withstanding temperature similar to those found upon reentry or partial reentry of a spacecraft. The housing 100 material is ideally non-conductive or inert. The housing 100 may comprise a front end 110 and a rear end 120. The front end 110 is ideally positioned during use so that the front end 110 comprises the hotter side of the housing 100, and the rear end 120 comprises the colder side of the housing 100 to create a temperature gradient between the front end 110 of the housing 100 and the rear end 120 of the housing 100. The housing 100 may comprise an outer surface 130 and an interior surface 140. The outer surface 130 of the housing 100 faces outwards and is exposed to the surroundings during use. The interior of the housing 100 may be adapted with hollow areas to hold the plurality of thermopiles 200, or the plurality of thermopiles 200 may be directly integrated into the housing 100. The plurality of thermopiles 200 are ideally positioned within the housing 100. In some embodiments, portions of the plurality of thermopiles 200 may be exposed on the outer surface 130 of the housing 100. In some embodiments, portions of the plurality of thermopiles 200 may be contained within the interior of the housing 100. These configurations further assist in creating temperature gradients between the plurality of thermopiles 200 to assist in energy generation using the Seebeck effect.

Each thermopile of the plurality of thermopiles 200 may comprise a leading end 210 and a trailing end 220. The leading end 210 is ideally positioned towards the front end 110 of the housing 100, and the trailing end 220 is ideally positioned towards the rear end 120 of the housing 100. Thus, the leading end 210 of each thermopile is positioned towards the “hotter” side of the housing 100, and the trailing end 220 of each thermopile is positioned towards the “cooler” side of the housing 100 to assist in energy generation using the Seebeck effect from this configuration's temperature differential. The plurality of thermopiles 200 may work in series or in parallel. In some embodiments, a single thermopile may be used.

Each thermopile may further comprise a plurality of thermocouples 300, as is known in the art. Each thermocouple may comprise a set of N and P nodes, the set of N and P nodes ideally being p-type and n-type semiconductor materials. The thermocouples may be joined in an S and Z configuration, such that each thermocouple is connected to another thermocouple at both ends, with the N node of one thermocouple being connected to the P node of another thermocouple. In the ideal embodiment, all sets of N and P nodes from each thermopile are equally exposed to the outer surface 130 of the housing 100, such that half of the P nodes are embedded under the outer surface, and half of the N nodes are embedded under the outer surface. This configuration allows for equal thermal conduction at each node. In the ideal embodiment, the N and P nodes are placed opposite each other in series.

Ideally, the plurality of thermocouples 300 of each thermopile are made of two types of different materials. The plurality of thermocouples 300 may use P-type and N-type nodes which may be made of different configurations of tungsten/rhenium-alloy and nickel alloys. The tungsten/rhenium-alloy thermocouple types may comprise: C, D, and G. The Nickel Alloy types may comprise: K, P, M, and N. Each one is made of a different material that varies in its thermal conduction ability, set A and B each having a high conduction and low conduction material pairing. The plurality of thermocouples may be connected in a solid-state construction of sets of interlocking thermocouples, forming the plurality of thermopiles 200.

The electrical connector 400 may comprise an electrical connection, wiring, or other electrical transmittance device that is well-known in the art. The electrical connector 400 is positioned and connected to transfer power from the plurality of thermopiles 200 to the power management circuit 500. In some embodiments, the use of a plurality of electric connectors is contemplated.

The power management circuit 500 is adapted to accept power or energy generated by the electrical connector 400, and may be adapted to distribute, manage, store, or transfer energy generated by the plurality of thermopiles 200 to a power storage device or other device. In some embodiments, the use of multiple power management circuits 500 is contemplated, such that a plurality of power management circuits 500 are used. In this embodiment, each thermocouple of the plurality of thermocouples 300 may be electrically connected to a power management circuit 500 of the plurality of power management circuits 500, such that each thermopile is connected to one power management circuit 500, and each power management circuit 500 is connected to one thermopile.

Various shapes and configuration may be used for the housing 100 to accommodate various use cases. For example, the housing 100 may be in the shape of a cone, allowing the housing 100 to be used as the nosecone for an aircraft or an orbital reentry vehicle. The housing 100 may be a wing, allowing the housing 100 to be used as wings for an aircraft, spacecraft, or other vehicle. The housing 100 may also be of a standard shape, such as a cylinder or sphere for other assorted use cases. The plurality of thermopiles 200 may be positioned in each shape such that a leading end 210 of the plurality of thermopiles 200 is positioned at the “hotter” end, and the trailing end 220 of the plurality of thermopiles 200 is positioned at the “cooler” end. For example, in a nose cone on an aircraft, the leading end 210 of the plurality of thermopiles 200 is positioned at the front of the nose cone that receives the most air resistance and friction, and the trailing end of the plurality of thermopiles 200 is positioned at the rear of the nose cone, where air resistance and heat are at the lowest. These configurations assist in creating a temperature differential between the leading and trailing ends 220 of the plurality of thermopiles 200 to generate energy using the Seebeck effect.

The use of multiple different configuration for the plurality of thermopiles 200 is contemplated, each configuration being better suited for different uses. In some embodiments, the plurality of thermopiles 200 may be oriented in a helical configuration from the front end 110 to the rear end 120 of the housing 100, with the plurality of thermopiles 200 being tightly coiled, such that the surface area of the outer surface 130 of the housing 100 covers the top of each thermopile. In this configuration, there is no “dead space” on the outer surface 130 of the housing 100, such that the exposed surface area of the housing 100 covers the thermopiles.

In other embodiments, the plurality of thermopiles 200 are arranged in a toroid configuration, and the plurality of thermopiles 200 are connected in sequence.

In other embodiments, the plurality of thermopiles 200 are arranged linearly along the axis of heat of the housing 100.

In other embodiments, the plurality of thermopiles 200 are arranged in a concentric ring configuration, with each concentric ring being connected in series to the next concentric ring.

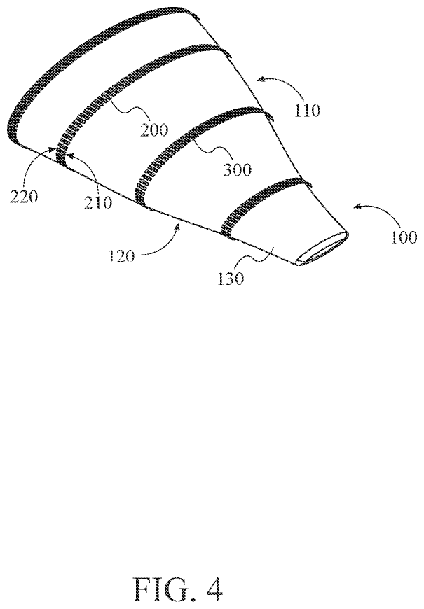

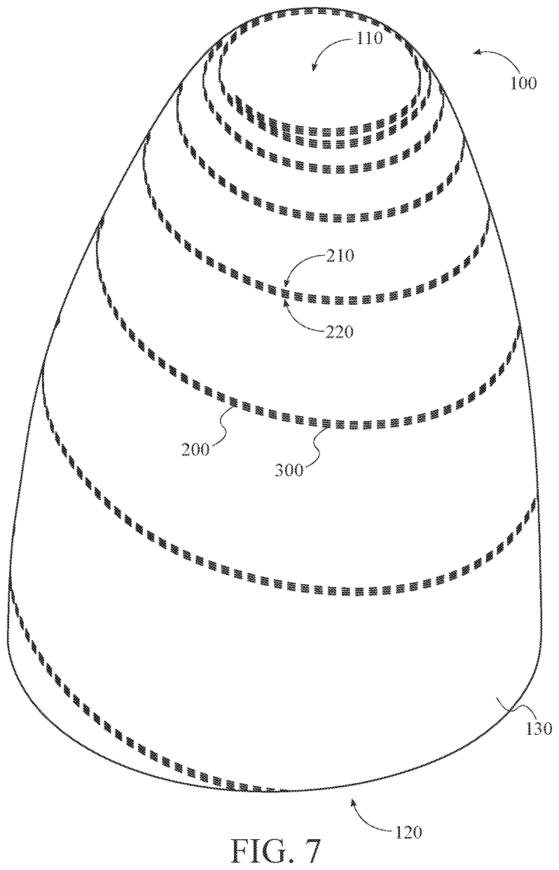

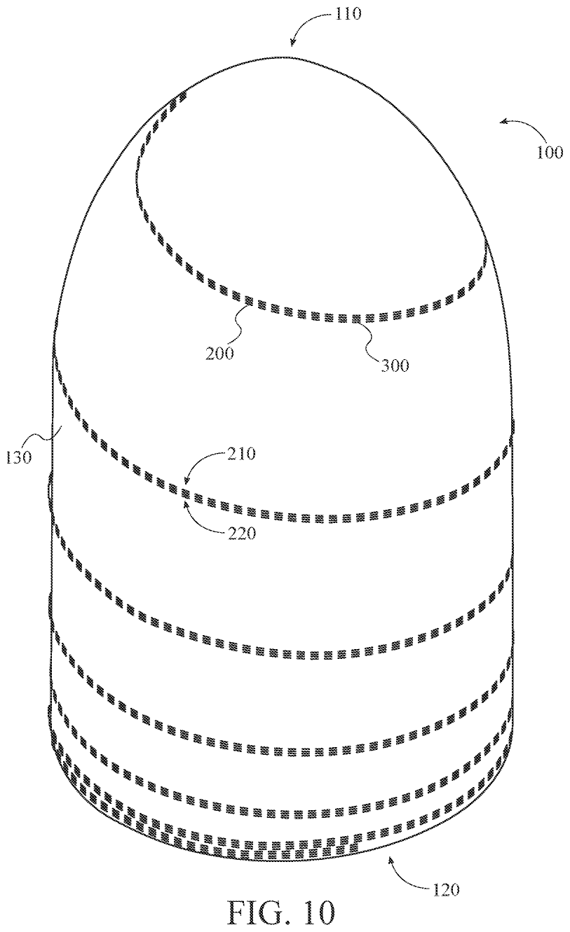

The figures show some exemplary configurations of both housing 100 shapes and thermopile configurations. FIGS. 1-3 demonstrate a housing 100 having a conical shape using a configuration of concentric rings. FIGS. 4-6 demonstrate a housing 100 having the shape of a wing with the plurality of thermopiles 200 being arranged in a toroidal configuration. FIGS. 7-9 demonstrate a housing 100 having a cylindrical shape, with the plurality of thermopiles 200 being oriented in a helical configuration from the front end 110 of the housing 100 to the rear end 120 of the housing 100. Likewise, FIGS. 10-12 show a housing 100 having a conical shape, with the plurality of thermopiles 200 being oriented in a helical configuration from the front end 110 of the housing 100 to the rear end 120 of the housing 100.

An ideal embodiment of the energy generation device is described below. The plurality of thermopiles 200 may comprise a first thermopile and a second thermopile. The first thermopile may comprise a first plurality of thermopiles 200, a first leading end 210 and a first trailing end 220. The second thermopile may comprise second plurality of thermopiles 200, a second leading end 210 and a second trailing end 220. The first thermopile may comprise a first set of N and P nodes. The second thermopile may comprise a second set of N and P nodes. In some embodiments, the first set and second set of N and P nodes made be made of separate materials, such that the first set of N and P nodes are comprised of a first and a second material, and the second set of N and P nodes are comprised of a third and a fourth material. Both the first set and the second set of N and P nodes may be equally exposed to the outer surface 130 of the housing 100, such that half of all the N nodes and half of all the P nodes are exposed to the outer surface 130 of the housing 100, allowing for equal thermal conduction at each node. The N and P nodes may be placed opposite to each other in series for both the first plurality of thermocouples 300 and the second plurality of thermocouples 300, such that each N node is connected to a P node, and vice versa. The purpose of this connection is to allow for controlled thermal expansion in the two materials that comprise the N and P nodes. The thermal transfer of energy into the nodes will produce an electrical current. The N and P nodes may be wrapped in parallel along the housing 100. The N and P nodes may be The N and P nodes are ideally positioned in the housing 100 to provide the greatest surface area and electrical flow possible.

The first leading end 210 and second leading end 210 may be positioned at the front end 110 of the housing 100. The first trailing end 220 and second trailing end may be positioned at the rear 120 of the housing 100. The first thermopile may be electrically connected to the electrical connector 400 in an-series distribution. The second thermopile may be electrically connected to the electrical connector 400 in an-series distribution. The electrical connector 400 may be electrically connected to the power management circuit 500. The first leading end 210 and second leading end 210 may be positioned at the front end 110 of the housing 100, while the first trailing end 220 and the second trailing end 220 may be positioned at the rear end 120 of the housing 100, facilitating the generation of a temperature differential between the leading end 210 and trailing end of the first thermopile and second thermopile. Ideally, the first thermopile and the second thermopile each comprise two different materials that comprise the thermocouples, and the housing provides an inert, non-conductive separation material. Thus, when the housing 100 experiences a high temperature at the front end 110 and a lower temperature at the rear end 120, the plurality of thermopiles 200 will generate energy through the Seebeck effect. It should be understood that the use of more than two thermopiles is contemplated.

Although the invention has been explained in relation to its preferred embodiment, it is to be understood that many other possible modifications and variations can be made without departing from the spirit and scope of the invention.

What is claimed is:

1. An energy generation device comprising:
a housing;
the housing comprising a front end, a rear end, and an outer surface;
a plurality of thermopiles;
an electrical connector;
a power management circuit;
the plurality of thermopiles being positioned within the housing;
the plurality of thermopiles comprising a plurality of thermocouples;
the plurality of thermopiles comprising a leading end and a trailing end;
each thermopile of the plurality of thermopiles comprising a set of N and P nodes;
the electrical connector being electrically connected to the power management circuit;
the leading end being positioned at a frontward end of the housing; and
the trailing end being positioned at a rearward end of the housing.

2. The energy generation device of claim 1, further comprising:
the plurality of thermopiles comprising a first thermopile and a second thermopile;
the first thermopile comprising a first leading end and a first trailing end;
the second thermopile comprising a second leading end and a second trailing end;
the first leading end and the second leading end being positioned at the front end of the housing; and
the first trailing end and the second trailing end being positioned at the rear end of the housing.

3. The energy generation device of claim 2, further comprising:
the first thermopile comprising a first plurality of thermocouples;
the second thermopile comprising a second plurality of thermocouples;
the first plurality of thermocouples comprising a first set of N and P nodes;
the second plurality of thermocouples comprising a second set of N and P nodes;
the first set of N and P nodes being placed opposite to each other in series, such that each N node is connected to a P node;
the second set of N and P nodes being placed opposite to each other in series, such that each N node is connected to a P node.

4. The energy generation device of claim 3, further comprising:
the first set of N and P nodes and the second set of N and P nodes being equally below the outer surface, such that half the N nodes and half the P nodes are below the outer surface.

5. The energy generation device of claim 4, further comprising:
the first thermopile being electrically connected to the electrical connector in an in-series distribution; and
the second thermopile being electrically connected to the electrical connector in an in-series distribution.

6. The energy generation device of claim 1, further comprising:
the plurality of thermopiles being oriented in a helical configuration from the front end to the rear end of the housing; and
the plurality of thermopiles being tightly coiled, such that the surface area of the outer surface of the housing covers the top of each thermopile.

7. The energy generation device of claim 1, further comprising:
the plurality of thermopiles is arranged in a toroid configuration; and
the plurality of thermopiles is continuously connected in sequence.

8. The energy generation device of claim 1, further comprising:
the plurality of thermopiles is arranged linearly along the axis of heat of the housing.

9. The energy generation device of claim 1, further comprising:
the housing being a cone.

10. The energy generation device of claim 1, further comprising:
the housing being a wing.

11. The energy generation device of claim 1, further comprising:
the housing being a cylinder.

12. The energy generation device of claim 1, further comprising:
the housing being a sphere.

13. An energy generation device comprising:
a housing;
the housing comprising a front end, a rear end, and an outer surface;
a plurality of thermopiles;
the plurality of thermopiles being positioned within the housing;
the plurality of thermopiles comprising a first thermopile and a second thermopile;
the first thermopile comprising a first leading end and a first trailing end;
the second thermopile comprising a second leading end and a second trailing end;
the first thermopile comprising a first plurality of thermocouples;
the second thermopile comprising a second plurality of thermocouples;
the first plurality of thermocouples comprising a first set of N and P nodes;
the second plurality of thermocouples comprising a second set of N and P nodes;
the first set of N and P nodes being placed opposite to each other in series, such that each N node is connected to a P node;
the second set of N and P nodes being placed opposite to each other in series, such that each N node is connected to a P node;
the first set of N and P nodes and the second set of N and P nodes being equally exposed to the outer surface, such that half the N nodes and half the P nodes are under the outer surface;
an electrical connector;
a power management circuit;
the first thermopile being electrically connected to the electrical connector in an in-series distribution;
the second thermopile being electrically connected to the electrical connector in an in-series distribution;
the electrical connector being electrically connected to the power management circuit;
the first leading end and the second leading end being positioned at the front end of the housing; and
the first trailing end and the second trailing end being positioned at the rear end of the housing.

14. The energy generation device of claim 13, further comprising:
the plurality of thermopiles being oriented in a helical configuration from the front end to the rear end of the housing; and
the plurality of thermopiles being tightly coiled, such that the surface area of the outer surface of the housing covers the top of each thermopile.

15. The energy generation device of claim 13, further comprising:
the plurality of thermopiles is arranged in a toroid configuration; and
the plurality of thermopiles is continuously connected in sequence.

16. The energy generation device of claim 13, further comprising:
the plurality of thermopiles is arranged linearly along the axis of heat of the housing.

17. The energy generation device of claim 13, further comprising:
the housing being a cone.

18. The energy generation device of claim 13, further comprising:
the housing being a wing.

19. The energy generation device of claim 13, further comprising:
the housing being a cylinder.

20. The energy generation device of claim 13, further comprising:
the housing being a sphere.
